(19) United States
(12) Patent Application Publication
(10) Pub. No.: US 2025/0057026 A1
(43) Pub. Date: Feb. 13, 2025

(54) ORGANIC LIGHT EMITTING DISPLAY APPARATUS INCLUDING LIGHT GUIDING PART

(71) Applicant: LG Display Co., Ltd., Seoul (KR)

(72) Inventors: SunWoong KIM, Paju-si (KR); JuHun MIN, Paju-si (KR); SeungSoo YANG, Paju-si (KR); DongUk KIM, Paju-si (KR)

(73) Assignee: LG Display Co., Ltd., Seoul (KR)

(21) Appl. No.: 18/795,932

(22) Filed: Aug. 6, 2024

(30) Foreign Application Priority Data
Aug. 9, 2023 (KR) 10-2023-0104404

(51) Int. Cl. H10K 59/80

(52) U.S. Cl. CPC H10K 59/8792

(57) ABSTRACT

An organic light emitting display apparatus in one example includes a substrate including a first subpixel and a second subpixel, a color filter layer including a first color filter disposed in the first subpixel on the substrate and a second color filter disposed in the second subpixel on the substrate, a black matrix disposed between the first color filter and second color filter, and a light guide part disposed on the first and second color filters of the color filter layer. The light guide part includes a plurality of lens patterns, and the sizes of the plurality of lens patterns are larger than the sizes of the first and second subpixels.

### CROSS-REFERENCE TO RELATED APPLICATIONS

This application claims priority to Korean Patent Application No. 10-2023-0104404 filed in the Republic of Korea on Aug. 9, 2023, the entire contents of which is hereby expressly incorporated by reference into the present application.

### BACKGROUND

### Technical Field

The present disclosure relates to an organic light emitting display apparatus including a light guide part capable of reducing reflectance by external light.

### Discussion of the Related Art

As more people in our society use various forms to communicate and share information, images, videos, etc., demands for display apparatuses to display such contents are also increasing. In response, various flat panel display apparatuses such as a liquid crystal display (LCD), an organic light emitting display (OLED), and a micro LED (light emitting diode) display have been researched and developed in recent years.

Among the display apparatuses, organic light-emitting displays are attracting attention as next-generation flat-panel displays because they have a high response speed, a low power consumption, and a self-luminous light configuration that does not require a separate light source unlike the liquid crystal displays.

The organic light emitting display apparatus displays an image through the light emission of a light emitting layer including a light emitting layer interposed between two electrodes. When light is introduced into the display apparatus from the outside, the introduced light is reflected by the electrodes and wirings provided inside the display apparatus to form reflected light. In this case, when the reflected light is emitted through the light emission surface of the display apparatus, the reflected light can be visually recognized as a mura pattern, for example, a rainbow mura or a ring mura. If this happens, it can be challenging or difficult to implement Real Black (or True Black) in the turn-off state of the display apparatus.

To solve or address this limitation, a light guide part can be introduced into the display apparatus. However, the height of the pattern included in the light guide part differs from each other, which can result in a contrast difference in which Sparkle (or Sparkling) is recognized. Sparkling is not desirable since it can render viewing of the screen tiresome and bring fatigue to the viewer's eyes. Further, it can make it difficult or challenging to implement or achieve Real Black in the display apparatus.

### SUMMARY OF THE DISCLOSURE

The present disclosure has been made to address the above-discussed and other limitations and disadvantages associated with the related art.

Accordingly, it is an object of the present disclosure to provide an organic light emitting display apparatus with an improved sparkle, which includes a plurality of lens patterns that can minimize or reduce the occurrence of Rainbow Mura and Ring Mura phenomena due to the reflection of external light, and which optimizes the size and height ratio H/D of the plurality of lens patterns according to the distance between the black matrix and the light guide part to reduce the contrast deviation between the plurality of lens patterns.

In accordance with an aspect of the present disclosure, the above and other objects can be accomplished by the provision of an organic light emitting display apparatus comprising a substrate including a first subpixel and a second subpixel, a color filter layer including a first color filter disposed in the first subpixel on the substrate and a second color filter disposed in the second subpixel on the substrate, a black matrix disposed between the first color filter and second color filter, and a light guide part disposed on the color filter layer, wherein the light guide part includes a plurality of lens patterns, and sizes of the plurality of lens patterns are larger than sizes of the first and second subpixels.

Furthermore, the above and other objects can be accomplished by the provision of an organic light emitting display apparatus comprising a substrate including a first subpixel and a second subpixel, a color filter layer including a first color filter disposed in the first subpixel on the substrate and a second color filter disposed in the second subpixel on the substrate, a black matrix disposed between the first color filter and second color filter, and a light guide part disposed on the color filter layer, wherein the light guide part includes a plurality of lens patterns, and a size of the plurality of lens patterns is less than ½ of a length or size of one of the first and second subpixels.

These and other objects of the present application will become more readily apparent from the detailed description given hereinafter. However, it should be understood that the detailed description and specific examples, while indicating embodiments of the invention, are given by way of illustration only, since various changes and modifications within the spirit and scope of the invention will become apparent to those skilled in the art from this detailed description.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of an organic light emitting display apparatus according to an embodiment of the present disclosure.

FIG. 2 is a cross-sectional view of an organic light emitting display apparatus according to an embodiment of the present disclosure. In this case, FIG. 2 corresponds to a cross-section taken along line I-I′ illustrated in FIG. 1.

FIG. 3 is a plan view showing a light guide part of an organic light emitting display apparatus according to an embodiment of the present disclosure in detail.

FIG. 4 is a cross-sectional view of a light guide part of an organic light emitting display apparatus according to an embodiment of the present disclosure. In this case, FIG. 4 is a cross-sectional view taken along line II-II′ illustrated in FIG. 3.

FIG. 5 is a cross-sectional view of an organic light emitting display apparatus according to another embodiment of the present disclosure. In this case, FIG. 5 corresponds to another example of a cross-section taken along line I-I′ illustrated in FIG. 1.

FIG. 6 is a cross-sectional view of an organic light emitting display apparatus according to another embodiment of the present disclosure. In this case, FIG. 6 corresponds to yet another example of a cross-section taken along line I-I′ illustrated in FIG. 1.

FIG. 7 is a cross-sectional view of an organic light emitting display apparatus according to another embodiment of the present disclosure. In this case, FIG. 7 corresponds to still another example of a cross-section taken along line I-I′ illustrated in FIG. 1.

FIG. 8A illustrates the plurality of lens patterns formed in a size of 35 μm according to an example of the present disclosure, and FIG. 8B illustrates the plurality of lens patterns formed in a size of 20 μm according to an example of the present disclosure.

### DETAILED DESCRIPTION OF THE EMBODIMENTS

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure can be only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part can also be present unless “only” is used. The terms in a singular form can include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween can be included, unless “just” or “direct” is used.

If it is mentioned that a first element is positioned “on” a second element, it does not mean that the first element is essentially positioned above the second element in the figure. The upper part and the lower part of an object concerned can be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other, and can be variously inter-operated with each other and driven technically. The embodiments of the present disclosure can be carried out independently from each other, or can be carried out together in a co-dependent relationship. Further, the terms “device” and “apparatus” are interchangeably used. All the components of each display device or apparatus according to all embodiments of the present disclosure are operatively coupled and configured. Furthermore, the term “can” encompasses all the meanings and coverages of the term “may.”

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode can be the drain electrode, and the drain electrode can be the source electrode. Further, the source electrode in any one embodiment of the present disclosure can be the drain electrode in another embodiment of the present disclosure, and the drain electrode in any one embodiment of the present disclosure can be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region can be a source electrode, and a drain region can be a drain electrode. Further, a source region can be a drain electrode, and a drain region can be a source electrode.

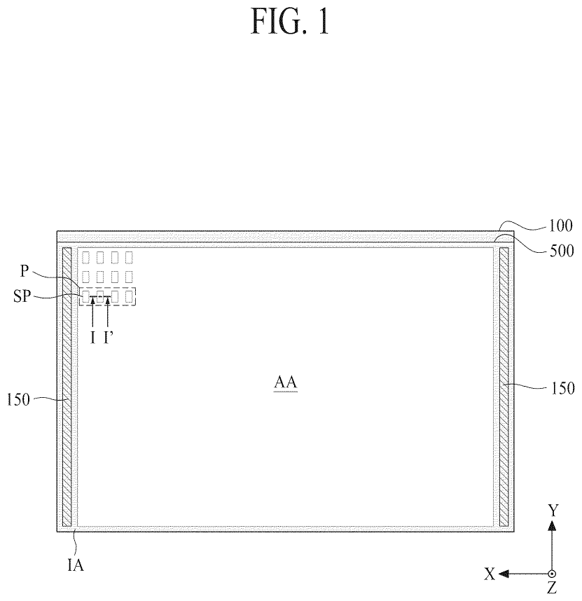

FIG. 1 is a plan view of an organic light emitting display apparatus according to an embodiment of the present disclosure.

Referring to FIG. 1, the organic light emitting display apparatus according to an embodiment of the present disclosure can include a display panel including a first substrate 100 and a second substrate 500 disposed opposite to the first substrate 100. The first and second substrates 100 and 500 can be bonded to each other.

The first substrate 100 can include one or more thin film transistors and can be a transparent glass substrate or a plastic substrate. The first substrate 100 can include a display area (or active area) AA in which an image is displayed and a non-display area (or inactive area) IA in which an image is not displayed, according to whether an image is displayed by a pixel. The non-display area IA can surround the display area AA entirely or only in part.

The display area AA can be an area in which an image is displayed, and can be or include a pixel array area, an active area, a pixel array unit, a display unit, or a screen. The display area AA can include a plurality of pixels P.

The plurality of pixels P can be disposed along a first direction (e.g., X direction) and a second direction (e.g., Y direction) crossing the first direction X. Each of the plurality of pixels P can be a unit region in which actual light is emitted. For example, the plurality of pixels P can be disposed to have a pixel pitch PP along the first direction X. The pixel pitch PP can be a size of each of the plurality of pixels P with respect to the first direction X, a distance between one side of each of two pixels P adjacent along the first direction X, or a distance between central portions of two pixels P adjacent along the first direction X.

Each of the plurality of pixels P can include a plurality of adjacent subpixels SP. The plurality of (or a group of) subpixels SP can constitute each of the plurality of pixels P. For example, three or four subpixels SP can constitute a pixel P, and can emit different color lights such as red, blue, green, etc. In examples, the first direction X can be a first length direction, a long side length direction, a horizontal direction, or a first horizontal direction of the first substrate 100. Further, the second direction Y can be a second length direction, a short side length direction, a vertical direction, a second horizontal direction, or a vertical direction of the first substrate 100.

The non-display area IA is an area in which no image is displayed, and can be a peripheral circuit area, a signal supply area, an inactive area, or a bezel area. The non-display area IA can be configured to surround the display area AA entirely or only in part. The display panel or the first substrate 100 can further include a peripheral circuit unit 150 disposed in the non-display area IA. The peripheral circuit unit 150 can include a gate driving circuit connected to the plurality of subpixels SP.

The second substrate 500 can be configured to overlap the display area AA. The second substrate 500 can be bonded to face the first substrate 100 through an adhesive member (or a transparent adhesive or optically clear adhesive), or can be disposed in a manner in which an organic material or an inorganic material is stacked on the first substrate 100. The second substrate 500 can be an upper substrate or an encapsulation substrate, and can correspond to encapsulating the first substrate 100.

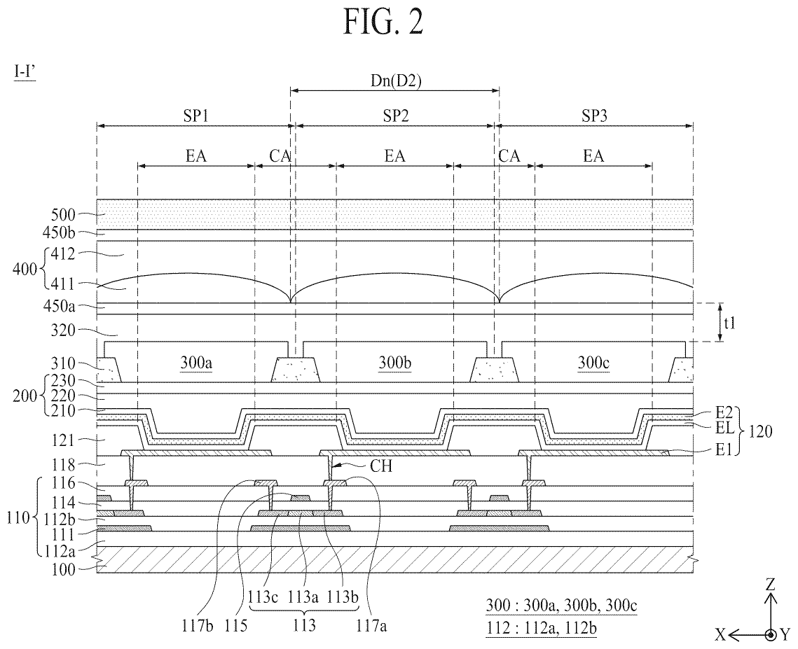

FIG. 2 is a cross-sectional view of an organic light emitting display apparatus according to an embodiment of the present disclosure. In this case, FIG. 2 corresponds to an example of a cross-section taken along line I-I′ illustrated in FIG. 1.

Referring to FIG. 2, the organic light emitting display apparatus according to an embodiment of the present disclosure can include a first substrate 100, a circuit element layer 110, a light emitting element layer 120, an encapsulation layer 200, a color filter 300, a light guide part 400, and a second substrate 500.

The first substrate 100 can include a thin film transistor, and can be a first substrate, a base substrate, a lower substrate, a transparent glass substrate, a transparent plastic substrate, or a base member.

The first substrate 100 can include a circuit element layer 110, a planarization layer 118, and a light emitting element layer 120, or all these layers can be disposed on the first substrate 100. The circuit element layer 110 can include buffer layers 112a and 112b and the pixel circuit.

The buffer layer 112 can include a lower buffer layer 112a and an upper buffer layer 112b.

The lower buffer layer 112a can be disposed on the entire first surface (or front surface) of the first substrate 100. The lower buffer layer 112a can serve to block diffusion of a material contained in the first substrate 100 into the transistor layer during a high-temperature process in a thin film transistor manufacturing process or can also serve to prevent external moisture or humidity from penetrating toward the light emitting element layer 120. Optionally, the lower buffer layer 112a can be omitted in some cases.

The upper buffer layer 112b can be disposed on the entire second surface (or rear surface) of the first substrate 100. The upper buffer layer 112b can separate the light blocking layer 111 from the active layer 113 of the thin film transistor.

The pixel circuit can include a driving thin film transistor disposed in a circuit area CA of each subpixel SP, where each subpixel SP can have at least one circuit area CA and a light emitting area EA adjacent to the at least one circuit area CA. The driving thin film transistor can include an active layer 113, a gate insulating layer 114, a gate electrode 115, an interlayer insulating layer 116, a source electrode 117a and a drain electrode 117b.

The active layer 113 can be formed of a semiconductor material based on any one of amorphous silicon, polycrystalline silicon, oxide, and organic material. The active layer 113 can include a channel region 113a, a source region 113b and a drain region 113c.

The gate insulating layer 114 can be formed in an island shape only on the channel region 113a of the active layer 113 or can be formed on the entire front surface of the first substrate 100 or the upper buffer layer 112b including the active layer 113.

The gate electrode 115 can be disposed on the gate insulating layer 114 to overlap the channel region 113a of the active layer 113.

The interlayer insulating layer 116 can be formed on the gate electrode 115 and the drain region 113c and the source region 113b of the active layer 113. The interlayer insulating layer 116 can be formed on the entire front surface of the first substrate 100 or the lower buffer layer 112a. For example, the interlayer insulating layer 116 can be formed of an inorganic material or an organic material.

The source electrode 117a can be disposed on the interlayer insulating layer 116 to be electrically connected to the source region 113b of the active layer 113, and the drain electrode 117b can be disposed on the interlayer insulating layer 116 to be electrically connected to the drain region 113c of the active layer 113.

The pixel circuit can further include at least one capacitor and at least one switching thin film transistor disposed in the circuit area CA together with the driving thin film transistor.

The organic light emitting display apparatus according to the present disclosure can further include a light blocking layer 111 provided under the active layer 113 of at least one of the driving thin film transistor and the switching thin film transistor. The light blocking layer 111 can be configured to minimize or prevent a change in a threshold voltage of the thin film transistor due to external light.

A protective layer can be additionally provided on the interlayer insulating layer 116. In this case, the protective layer can be configured on a pixel circuit. For example, the protective layer can be configured to surround the drain electrode 117b, the source electrode 117a, and the interlayer insulating layer 116 of the driving thin film transistor. The protective layer can be formed of an inorganic insulating material, and can be expressed in terms such as a passivation layer.

The planarization layer 118 can be provided on the circuit element layer 110. The planarization layer 118 can be formed on the entire display area and the rest of the non-display area except for the pad area. For example, the planarization layer 118 can include an extension part (or an expansion part) extending or expanding from the display area toward the non-display area except for the pad area. Thus, the planarization layer 118 can have a size relatively larger than that of the display area.

The planarization layer 118 according to an embodiment can be formed to have a relatively large thickness to provide a planarization surface on the circuit element layer 110. For example, the planarization layer 118 can be made of an organic material such as photoacrylic, benzocyclobutene, polyimide, fluorine resin, etc.

Further, the planarization layer 118 can include a light extraction unit disposed in each subpixel SP. The light extraction unit can be formed in the planarization layer 118 to overlap the light emitting area EA defined in the subpixel area SPA of each subpixel SP. In this case, the light extraction unit can be formed in the planarization layer 118 to have a curved portion (or a non-flat portion). In this case, the curved portion can include a plurality of concave portions and a convex portion. The light extraction unit can be formed in the planarization layer 118 to have a curved (or uneven) shape. When the light extraction unit is provided in the planarization layer 118, the external extraction efficiency of light emitted from the light emitting element layer 120 can increase.

The light emitting element layer 120 can overlap the light emitting area EA of each subpixel SP. For instance, the light emitting element layer 120 can be disposed in the light emitting area EA of each subpixel SP. The light emitting element layer 120 according to an embodiment can include a first electrode E1, a light emitting layer EL, and a second electrode E2, where the light emitting layer EL is disposed between the first and second electrode E1 and E2. In an example, the first electrode E1, the light emitting layer EL, and the second electrode E2 can be configured to emit light toward the second substrate 500 according to a top emission method. However, the present disclosure is not limited thereto, and can be configured to emit light toward the first substrate 100 according to a bottom emission method.

The first electrode E1 can be formed on the planarization layer 118 of the subpixel area SPA to be electrically connected to the source electrode 117a of the driving thin film transistor. One end of the first electrode E1 adjacent to the circuit area CA can be electrically connected to the source electrode 117a of the driving thin film transistor through a contact hole or electrode contact hole CH provided in the planarization layer 118 and the protective layer 118.

The light emitting layer EL can be formed on the first electrode E1 to be in direct contact with the first electrode E1.

The emission layer EL according to an embodiment can include two or more organic emission layers for emitting white light. For example, the emission layer EL can include a first organic emission layer and a second organic emission layer for emitting white light by mixing the first light and the second light.

The second electrode E2 can be formed on the light emitting layer EL to be in direct contact with the light emitting layer EL. The second electrode E2 can be formed (or deposited) on the light emitting layer EL to have a relatively thin thickness compared to the light emitting layer EL.

The first electrode E1 according to an embodiment of the present disclosure can include a metal material having a high reflectivity in order to reflect light emitted from the light emitting layer EL and incident thereto toward the second substrate 500. For example, the first electrode E1 can include a single-layered structure or a multilayer structure formed of any one material selected from aluminum (Al), silver (Ag), molybdenum (Mo), gold (Au), magnesium (Mg), calcium (Ca), or barium (Ba). The first electrode E1 can be an anode electrode.

Meanwhile, when the light extraction unit is provided in the planarization layer 118, the first electrode E1, the light emitting layer EL and the second electrode E2 can have a surface shape that directly follows a surface morphology of the light extraction unit including a plurality of convex portions and a plurality of concave portions. For example, the first electrode E1, the light emitting layer EL, and the second electrode E2 are formed in a conformal shape that directly follows (or conforms to) the surface shape (or morphology) of the light extraction unit by a deposition process of a transparent conductive material, and thus can have a cross-sectional structure having the same shape as the light extraction unit.

The organic light emitting display apparatus according to the example configuration of the present disclosure can further include a bank layer 121. The bank layer 121 can be disposed on the planarization layer 118 and the edge of the first electrode E1. The bank layer 121 can be formed of a transparent material or an opaque material. For example, the bank layer 121 can be a transparent bank layer or a black bank layer. In an example, the bank layer 121 can be formed of a photosensitizer including a black pigment, and in this case, the bank layer 121 can also serve as a light blocking member between the adjacent subpixels SP.

The encapsulation layer 200 can be formed on the first substrate 100 to surround or cover the light emitting element layer 120. The encapsulation layer 200 can be formed on the second electrode E2. For example, the encapsulation layer 200 can surround or cover a display area. The encapsulation layer 200 can protect the thin film transistor and the light emitting layer EL from external impact and can serve to prevent one or more of oxygen, moisture and other particles from penetrating into the light emitting layer EL.

The encapsulation layer 200 according to an example of the present disclosure can include a plurality of inorganic encapsulation layers 210, 230. In addition, the encapsulation layer 200 can further include at least one organic encapsulation layer 220 interposed between the plurality of inorganic encapsulation layers 210, 230. The encapsulation layer 200 according to another embodiment can be changed into a filler surrounding the entire display area, and in this case, the second substrate 500 can be bonded to the first substrate 100 through a filler. The filler can include a getter material that absorbs oxygen or/and moisture.

The color filter 300 can be provided on the encapsulation layer 200. Specifically, it can be disposed between the encapsulation layer 200 and the second substrate 500. The color filter 300 can be disposed between the encapsulation layer 200 and the second substrate 500 to overlap at least one light emitting area EA. For example, the color filter 300 can be formed directly on the upper surface of the encapsulation layer 200 to overlap the light emitting area EA. In this case, the color filter 300 can directly contact the upper surface of the encapsulation layer 200. However, the present disclosure is not limited thereto, and the color filter 300 can be disposed on the inner surface of the second substrate 500 facing the upper surface of the encapsulation layer 200 to overlap the light emitting area EA. For example, the second substrate 500 having the color filter 300 can be coupled to the encapsulation layer 200 via a transparent adhesive member.

The color filter 300 can include a first color filter 300a, a second color filter 300b, and a third color filter 300c. The color filter 300 can have a size wider than that of the light emitting area EA. For instance, each of the first to third color filters 300a, 300b, 300c can have a width that is greater than a width of the corresponding light emitting area EA. In an example, the color filter 300 may have a size corresponding to the entire subpixel area SPA of each subpixel SP, thereby reducing light leakage between adjacent subpixels SP.

The color filter 300 can be provided in the plurality of subpixels SP1, SP2, and SP3. For example, the first color filter 300a can be provided in the area where the first subpixel SP1 is formed, and the second color filter 300b can be provided in the area where the second subpixel SP2 is formed. The third color filter 300c can be provided in the area where the third subpixel SP3 is formed.

The color filter 300 according to the example of the present disclosure can be configured to transmit a wavelength of a color set in the corresponding subpixel SP. For example, when one pixel P is composed of the first to third subpixels SP1, SP2 and SP3, the color filter 300 can include a red color filter (e.g., 300a) provided in the first subpixel SP1 for emitting red light, a green color filter (e.g., 300b) provided in the second subpixel SP2 for emitting green light, and a blue color filter (e.g., 300c) provided in the third subpixel SP3 for emitting blue light. On the other hand, when the plurality of subpixels P include a fourth subpixel for emitting white light, the color filter 300 may not be provided (or is absent) in a region where the fourth subpixel for emitting the white light is formed, or can include a transparent material to compensate for a step difference from the other color filters 300a, 300b, and 300c, thereby emitting the white light.

The black matrix 310 can be provided between the plurality of color filters 300, and the black matrix 310 can overlap the bank layer 121.

The black matrix 310 can be arranged to overlap the remaining area of each subpixel SP excluding the light emitting area EA. Alternatively, the remaining area of each subpixel SP excluding the light emitting area EA can include a stacked structure of at least two or more color filters instead of the black matrix 310. For example, the remaining area of each subpixel SP excluding the light emitting area EA can include a stacked structure of at least two color filters among a red color filter, a green color filter, and a blue color filter. A stacked structure of at least two color filters can replace the black matrix 310 and prevent color mixing between adjacent subpixels SP.

The overcoating layer 320 can be provided on the color filter 300 and the black matrix 310, and the overcoating layer 320 can protect the color filter 300 and planarize the level difference caused by the color filter 300 and the black matrix 310.

The light guide part 400 and the second substrate 500 can be provided on the color filter 300 and the overcoating layer 320. The second substrate 500 can be made of a plastic material, a glass material, or a metal material. Meanwhile, if the encapsulation layer 200 includes the plurality of inorganic encapsulation layers, the second substrate 500 can be omitted.

Optionally, when the encapsulation layer 200 is changed to a filler, the second substrate 500 can be combined with a filler, and in this case, the second substrate 500 can be made of a plastic material, a glass material, or a metal material.

The light guide part 400 can be provided between the color filter 300 and the second substrate 500. The light guide part 400 can be disposed or configured on a first surface of the second substrate 500, for example, a second surface (or light emitting surface) opposite to the upper surface, for example, a lower surface.

The light guide part 400 according to an embodiment of the present disclosure can be coupled to the upper surface of the overcoating layer 320 via a lower adhesive member 450a, and can be coupled to the lower surface of the second substrate 500 via an upper adhesive member 450b (or the first transparent adhesive member). For example, the light guide part 400 can be coupled to the entire upper surface of the overcoating layer 320 via the lower adhesive member 450a and can be coupled to the entire lower surface of the second substrate 500 via the upper adhesive member 450b. In this case, the light guide part 400 can have the same size as the lower surface of the second substrate 500.

The light guide part 400 can be configured to improve black visibility characteristics due to a reflection of external light in a non-driving or off state of the organic light emitting display apparatus. For example, in the non-driving or off state of the organic light emitting display apparatus, light incident from the outside is reflected by the electrodes and wirings of the circuit element layer 110, which can form reflected light. In that case, the reflected light can form a rainbow mura (or rainbow stain pattern) that has a rainbow color and can spread radially and/or a circular ring pattern in a radial form due to the dispersion characteristics of light according to diffraction characteristics.

As a result, the reflected light can cause multiple interferences and/or reinforcement interferences of light according to the difference in refractive angles for each wavelength, which can generate a rainbow mura and/or a circular ring pattern in the form of radiation, thereby reducing black visibility characteristics of the organic light emitting display apparatus.

To address this issue, the light guide part 400 according to an embodiment of the present disclosure is provided, which can be configured to diffract and/or scatter external light incident into the display apparatus through the second substrate 500 from the outside based on the light refracting principle according to the cross-sectional shape having the refractive index difference, or to redisperse (or disperse) the diffraction dispersion spectrum of the reflected light. For example, the light guide part 400 according to the present disclosure can suppress, reduce or minimize the occurrence of the radial rainbow mura phenomenon through mixing between adjacent spectra according to the diffraction order of the reflected light by reducing the intensity of the diffraction dispersion spectrum or redispersing the diffraction dispersion spectrum to greatly expand the size of the spectrum.

In examples, the light guide part 400 can include a plurality of lens pattern 411 and a filling layer 412. The plurality of lens pattern 411 can diffract and/or scatter external light incident on the light emitting element layer 120 from the outside based on the light refraction principle having a difference in refractive index, or diffract and/or scatter the reflected light. Accordingly, the occurrence of a rainbow mura and/or a circular ring pattern can be eliminated, reduced or minimized by canceling or minimizing multiple interferences and/or reinforcing interferences of the reflected light. As such, according to an embodiment of the present disclosure, any decrease in the black vision characteristics of the display apparatus, which may be caused by the reflection of external light, can be reduced or eliminated, and real black status (Real Black or True Black) in the display apparatus can be realized in a non-driving or off state of the display apparatus. For example, the light guide part 400 can be a light guide pattern unit, a light refracting unit, a light refracting member, a spectrum dispersion unit, a spectrum reduction unit, or a diffraction spectrum dispersion unit.

According to one embodiment of the present disclosure, each of the plurality of lens patterns 411 can be provided in a hemispherical shape. However, the shape of the plurality of lens patterns 411 is not limited to a hemisphere, and two or more adjacent lens patterns among the plurality of lens patterns 411 can be formed to overlap, and the plurality of lens patterns 411 can be formed to overlap. The shape can be polygonal, and various shapes can be selected depending on the level of industry or need. The lens patterns 411 can have regularly sized and/or shaped lens in one example.

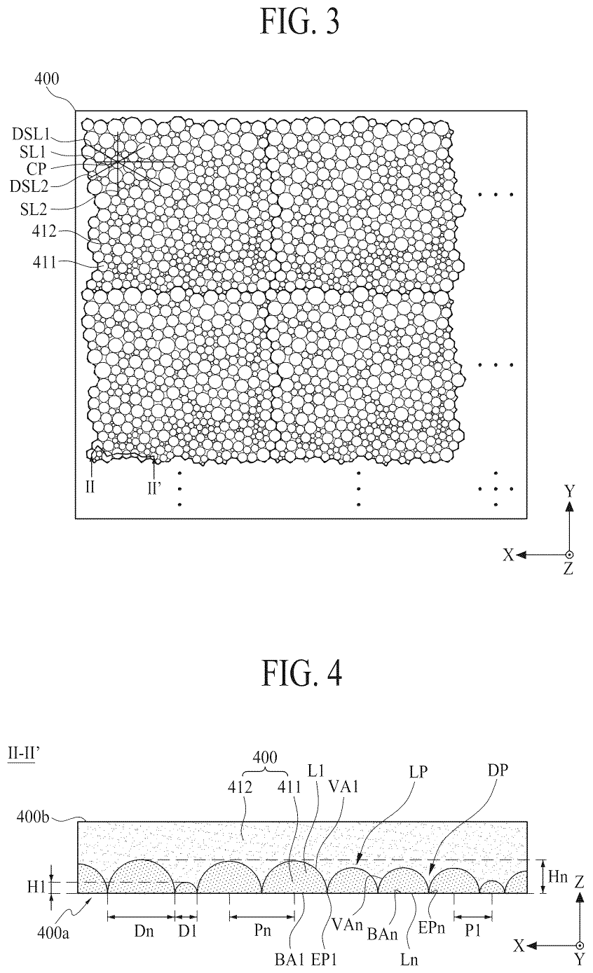

As a variation, the plurality of lens patterns 411 can be formed irregularly and arranged in an irregular configuration/size. The plurality of lens patterns 411 can prevent external light introduced from the outside of the organic light emitting display apparatus from being reflected by a plurality of electrodes, wirings, and circuits provided in the display apparatus, which may generate Mura (for example, Rainbow Mura or Ring Mura). Specifically, by arranging the plurality of lens patterns 411 irregularly, it is possible to prevent or minimize the occurrence of mura that can be visible to viewers due to certain regularity. Meanwhile, the irregular arrangement of the plurality of lens patterns 411 according to aspects of the present disclosure will be described later in more detail with reference to FIGS. 3 and 4.

Referring still to FIG. 2, according to one embodiment of the present disclosure, the light guide part 400 can be provided on the color filter 300, the black matrix 310 and the overcoating layer 320, and can establish a first thickness t1 with respect to the color filter 300. Specifically, a distance between the lower surface of the light guide part 400 and the upper surface of the color filter 300 can be designated as the first thickness t1.

That is, the light guide part 400 and the color filter 300 can be formed to be spaced apart from each other, and the first thickness t1, which is the distance between the light guide part 400 and the color filter 300, can be 30 μm or less.

According to an embodiment of the present disclosure, when the first thickness t1 is 30 μm or less, any one pattern among the plurality of lens patterns 411 of the light guide part 400 can overlap any one of the light emitting area EA. By forming in this way, light emitted from one of the light emitting area EA can pass through only one of the plurality of lens patterns 411 that overlap the light emitting area EA.

Each of the plurality of lens patterns 411 of the light guide part 400 can be formed to have a size larger than the plurality of subpixels SP. The size Dn of each of the plurality of lens patterns 411 of the light guide part 400 can be formed to be larger than that of the plurality of subpixels SP. For example, among the plurality of lens patterns 411, a lens pattern provided in the second subpixel SP2 can have a second size D2, and in this case, the second size D2 can be greater than the size of the second subpixel SP2. Here, the size Dn in the cross-sectional view can be a width, but other dimension may be used. Meanwhile, the size of one subpixel among the plurality of subpixels SP can be defined as the distance from the center of the bank layer 121 defining each subpixel SP to the center of the other adjacent bank layer 121. Alternatively, it can be defined as the distance between the center of one black matrix 310 overlapping the bank layer 121 and the center of another adjacent black matrix 310.

According to one embodiment of the present disclosure, the size Dn of each of the plurality of lens patterns 411 can be 10 μm or more and 100 μm or less.

That is, if the size Dn of each of the plurality of lens patterns 411 is less than 10 μm, the plurality of lens patterns 411 can become smaller than the size of the plurality of subpixels SP and sparkle can be visible. On the other hand, if the size Dn of each of the plurality of lens patterns 411 exceeds 100 μm, the plurality of lens patterns 411 can be visually recognized and the quality of an image can be deteriorated by the plurality of lens patterns 411.

According to one embodiment of the present disclosure, the size Dn of each of the plurality of lens patterns 411 is formed to be larger than each of the subpixels SP1, SP2, and SP3 in each of the plurality of pixels P, so that in the organic light emitting display apparatus according to the embodiment of the present disclosure, Sparkle can be removed, reduced or minimized, which improves performance and user experience significantly.

Specifically, according to the present disclosure, the light emitted from the second subpixel SP2 can be refracted while passing through one of the plurality of lens patterns 411 that overlap the second subpixel SP2. In this case, the light emitted from the second subpixel SP2 may not pass through another one of the plurality of lens patterns 411 which is adjacent to the one of the plurality of lens patterns 411. As a result, excessive refraction is prevented and sparkle can be effectively eliminated or minimized.

Furthermore, according to an embodiment of the present disclosure, the plurality of lens patterns 411 can have a height ratio H/D of 10% or more and 40% or less. In this case, the height ratio H/D for each lens pattern 411 can be defined as the ratio of the height (see H in FIG. 4) to the size Dn (e.g., width) of each of the plurality of lens patterns 411.

That is, if the height ratio H/D of the plurality of lens patterns 411 is less than 10%, light introduced from the outside of the organic light emitting display apparatus is reflected and Mura occurs. On the other hand, if the height ratio H/D of the plurality of lens patterns 411 exceeds 40%, Sparkle can be visually recognized due to a height difference between the highest point and the lowest point of the plurality of lens patterns 411.

However, according to the present disclosure, the height ratio H/D of the plurality of lens patterns 411 can preferably be 20% or more and 30% or less. When the height ratio H/D of the plurality of lens patterns 411 is 20% or more and 30% or less, Sparkles generated when light emitted from the plurality of subpixels P according to an embodiment of the present disclosure passes through the plurality of lens patterns 411 can be effectively and advantageously removed or minimized.

According to an embodiment of the present disclosure, since the height ratio H/D of the plurality of lens patterns 411 is 10% or more and 40% or less (preferably, the height ratio H/D of the plurality of lens patterns 411 is 20% or more and 30% or less), light is prevented from being excessively refracted between the plurality of lens patterns 411, so that a sparkle can be effectively removed or minimized in the present display apparatus.

In FIG. 2, the shape in which the plurality of lens patterns 411 do not overlap each other but meet at end points is shown, but the present disclosure is not limited to this and the plurality of lens patterns 411 can be formed to overlap each other. In this case, as the plurality of lens patterns 411 overlap each other (e.g., end portions of the lens patterns overlap with each other and have a specific thickness), the concave portion formed between the plurality of lens patterns 411 is controlled so that sparkle can be removed or minimized.

According to an embodiment of the present disclosure, the filling layer 412 can be provided on the plurality of lens patterns 411. The plurality of lens patterns 411 can have a first refractive index, and the filling layer 412 can have a second refractive index. In this case, the second refractive index of the filling layer 412 can be greater than the first refractive index of the plurality of lens patterns 411.

The difference between the second refractive index and the first refractive index can be 0.05 or more and 0.40 or less. On the other hand, when the difference in refractive index between the filling layer 412 and the plurality of lens patterns 411 is less than 0.05, the reliability of the material can deteriorate, whereas when the refractive index difference exceeds 0.40, Mura can be recognized when the organic light emitting display apparatus is in a non-driving state.

In the present disclosure, by having the difference between the second refractive index and the first refractive index to range from 0.05 to 0.40, Mura pattern, for example, a rainbow mura or a ring mura generated when light introduced from the outside of the light guide part 400 is reflected from electrodes and wiring inside the organic light emitting display apparatus can be effectively prevented or minimized.

Meanwhile, the organic light emitting display apparatus according to an embodiment of the present disclosure can additionally include a light transmitting member. The light transmitting member is provided on the light guide part 400 to block light coming from the outside from being reflected by a pixel circuit, etc.

Accordingly, the organic light emitting display apparatus according to an embodiment of the present disclosure includes the light guide part 400, so that blackness or black visibility characteristics due to the reflection of external light can be improved, and the occurrence Mura pattern, for example, a rainbow mura or a ring mura can be minimized or reduced, thereby realizing real black in a non-driving or off state of the display apparatus.

FIG. 3 is a plan view showing a light guide part of an organic light emitting display apparatus according to an embodiment of the present disclosure in detail. FIG. 4 is a cross-sectional view of a light guide part of an organic light emitting display apparatus according to an embodiment of the present disclosure. In this case, FIG. 4 is a cross-sectional view taken along line II-II′ illustrated in FIG. 3. The light guide part in any of the figures shown and/or discussed in the present application can be applied to any display apparatus shown in the figures and/or discussed in the present application.

Referring to FIGS. 3 and 4, the light guide part 400 according to an embodiment of the present disclosure can include a plurality of lens patterns 411 and a filling layer 412.

The plurality of lens patterns 411 in FIGS. 3 and 4 can be the same or similar features as the lens patterns 411 in FIG. 2, except for the irregular nature of the lens patterns 411 in FIGS. 3 and 4, and thus description of similar features will be omitted or may be briefly provided.

Each of the plurality of lens patterns 411 have lower surfaces BA1 to BAn corresponding to a portion of the lower surface 400a of the light guide part 400, and a convex surface VA1 to VAn formed convexly (or projecting) from the lower surfaces BA1 to BAn, where n is a real number such as an integer greater than 1.

One or more center points CP of the plurality of lens patterns 411 can include a first straight line SL1, a second straight line SL2, a first diagonal straight line DSL1, and a second diagonal straight line DSL2. For example, the pitches P1 to Pn between two adjacent lens patterns among the plurality of lens patterns 411 can be different along at least one of a first direction X, a second direction Y, and a diagonal direction between the first direction X and the second direction Y. For example, the plurality of lens patterns 411 can be configured to have different pitches P1 to Pn along at least one of the first direction X, the second direction Y, and the diagonal direction between the first direction X and the second direction Y.

At least some of the plurality of lens patterns 411 according to another embodiment of the present disclosure can be arranged to be connected to each other. At least some of the plurality of lens patterns 411 can be arranged to non-overlap (not overlap) and to be connected to each other. The plurality of lens patterns 411 can be configured to be non-overlapping and connected to each other along at least one of the first direction X, the second direction Y, and a diagonal direction between the first direction X and the second direction Y. For example, the bottom surfaces BA1 to BAn of the plurality of lens patterns 411 can be connected (or contacted) to the bottom surfaces BA1 to BAn of the lens patterns L1 to Ln adjacent to each other along one or more of the first direction X, the second direction Y, and the diagonal direction between the first direction X and the second direction Y. For example, the end points EP1 to EPn of the lower surfaces BA1 to BAn of each of the plurality of lens patterns 411 can be connected (or in contact) with the end points EP1 to EPn of the lower surfaces BA1 to BAn adjacent to each other along one or more of the first direction X, the second direction Y, and the diagonal direction between the first direction X and the second direction Y.

Meanwhile, the plurality of lens patterns 411 can be spaced apart from each other at a certain distance. In this case, the end points EP1 to EPn of the lower surfaces BA1 to BAn of the plurality of lens patterns 411 may not be connected to the end points EP1 to EPn of the lower surfaces BA1 to BAn adjacent to each other along one or more of the first direction X, the second direction Y, and the diagonal direction between the first direction X and the second direction Y. When formed in this way, the filling layer 412 can be provided in a region between the plurality of lens patterns 411, so that the filling layer 412 can be in contact with a part of the lower surface 400a of the light guide part 400.

The plurality of lens patterns 411 can have different sizes D1 to Dn. For example, since the plurality of lens patterns 411 can be non-overlapping and connected to each other along at least one or more of the first direction X, the second direction Y, and the diagonal direction between the first direction X and the second direction Y, each or some of the plurality of lens patterns 411 can have a different size D1 to Dn. For example, the plurality of lens patterns 411 can include a first plurality of lens patterns having a relatively large size and a second plurality of lens patterns provided between the first plurality of lens patterns having the relatively large size and having a relatively small size. In this case, the second plurality of lens patterns having the relatively small size can be disposed or filled between the first plurality of lens patterns having the relatively large size.

The plurality of lens patterns 411 can have different heights H1 to Hn. For example, each or some of the plurality of lens patterns 411 can have a different height H1 to Hn from the lower surface 400a of the light guide part 400. Having different heights and sizes for the lens patterns 411 can improve the performance and operation of the light guide part 400.

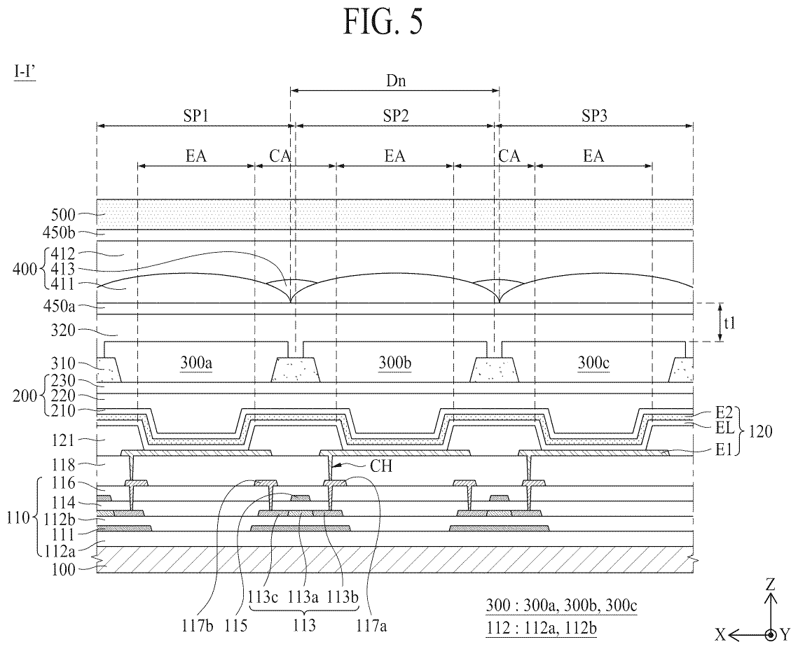

FIG. 5 is a cross-sectional view of an organic light emitting display apparatus according to another embodiment of the present disclosure. In this case, FIG. 5 corresponds to another example of a cross-section taken along line I-I′ illustrated in FIG. 1. Meanwhile, since the embodiment of FIG. 5 is the same as the embodiment of FIG. 2 except that a lens connection part is additionally provided between the plurality of lens patterns, the different configurations will be mainly described below.

Referring to FIG. 5, a lens connection part 413 can be provided between the plurality of lens patterns 411. The lens connection part 413 can be formed of a material having the same refractive index as the plurality of lens patterns 411, and can be irregularly disposed on the light guide part 400.

According to this embodiment of the present disclosure, the lens connection part 413 can be provided between the plurality of lens patterns 411, so that the concave area between the plurality of lens patterns 411 can be filled with the lens connection part 413.

The lens connection part 413 can be provided between the plurality of lens patterns 411, and the lens connection part 413 can have different sizes. For example, as shown in FIG. 5, the lens connection part 413 provided between the first subpixel SP1 and the second subpixel SP2, and another lens connection part 413 provided between the second subpixel SP2 and the third subpixel SP3 can have different sizes or heights.

By forming in this way, since the height difference between the area between the plurality of lens patterns 411 and the highest point of the any one of the plurality of lens pattern 411 can be reduced by the lens connection part 413, Sparkle can be further eliminated or minimized in the organic light emitting display apparatus of the present disclosure.

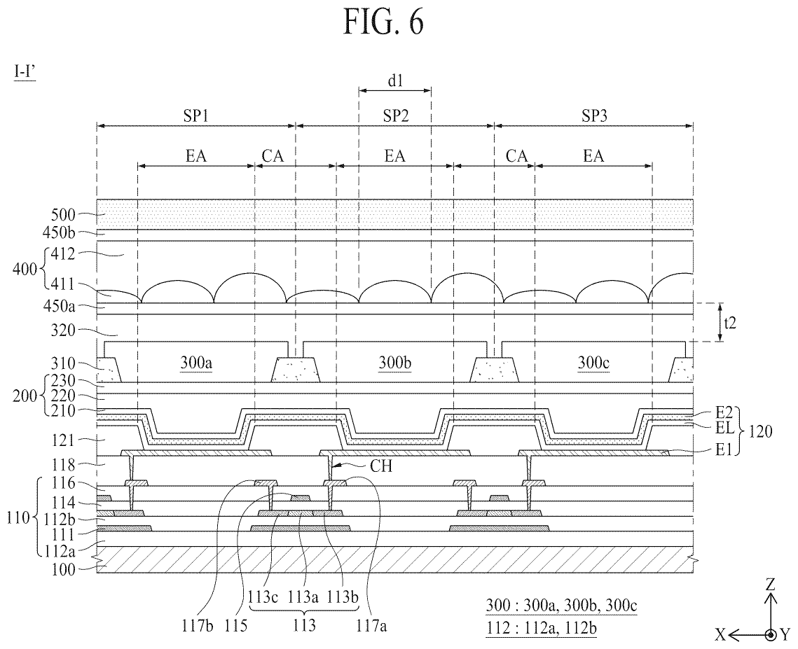

FIG. 6 is a cross-sectional view of an organic light emitting display apparatus according to another embodiment of the present disclosure. In this case, FIG. 6 corresponds to another example of a cross-section taken along line I-I′ illustrated in FIG. 1. Meanwhile, since the embodiment of FIG. 6 is the same as the embodiment of FIG. 2 except for the distance between the black matrix 310 and the light guide part 400 and the plurality of lens patterns 411, the different configurations will be mainly described below.

Referring to FIG. 6, according to the organic light emitting display apparatus in this embodiment of the present disclosure, the color filter 300 and the light guide part 400 can be spaced apart from each other, so that the upper surface of the color filter 300 and the lower surface of the light guide part 400 can be spaced apart from each other by a second thickness t2. In this case, the second thickness t2 can exceed 30 μm and be 600 μm or less.

According to this embodiment of the present disclosure, when the second thickness t2 exceeds 30 μm and is equal to or less than 600 μm, two or more patterns among the plurality of lens patterns 411 of the light guide part 400 can overlap any one of the light emitting areas EA. By forming in this way, light emitted from one of the light emitting areas EA can pass through two or more lens patterns among the plurality of lens patterns 411 that overlap the light emitting area EA. In other words, the plurality of lens patterns 411 can have a size d1 (e.g., width) that is less than ½ of the length (e.g., width) of the plurality of subpixels SP. In this case, the length (e.g., width) of each of the plurality of subpixels SP can be defined as the distance from the center of the bank layer 121 defining the light emitting area EA to the center of the other adjacent bank layer 121. Here, the length (e.g., width) of each subpixel (e.g., SP2) is indicated by the arrows defining the boundary of the subpixel SP2.

According to another embodiment of the present disclosure, for example, three adjacent lens patterns among the plurality of lens patterns 411 can be provided to overlap an area where the second subpixel SP2 is formed. In this case, since the light emitted from the second subpixel SP2 passes through three adjacent lens patterns among the plurality of lens patterns 411, the light emitting area EA of the second subpixel SP2 can overlap the plurality of lens patterns, for example, three lens patterns. Accordingly, by providing the plurality of lens patterns in the light emitting area EA, since the deviation in the degree to which the light emitted from the second subpixel SP2 is refracted as it passes through the plurality of lens patterns 411 is reduced as a whole, Sparkle can be effectively removed or minimized in the organic light emitting display apparatus of the present disclosure.

The size d1 of each of the plurality of lens patterns 411 according to another embodiment of the present disclosure can exceed 0 and be equal to 35 μm or less. The size d1 of each of the plurality of lens patterns 411 can preferably be equal to 10 μm or more and equal to 20 μm or less.

Meanwhile, unlike the embodiment of FIG. 6, the organic light emitting display apparatus according to another embodiment of the present disclosure may not be provided with a lens connection part (see 413 in FIG. 5) between the plurality of lens patterns 411. By forming in this way, sparkle of the organic light emitting display apparatus according to another embodiment of the present disclosure can be effectively removed or minimized when the second thickness t2 exceeds 30 μm and is equal to or less than 600 μm.

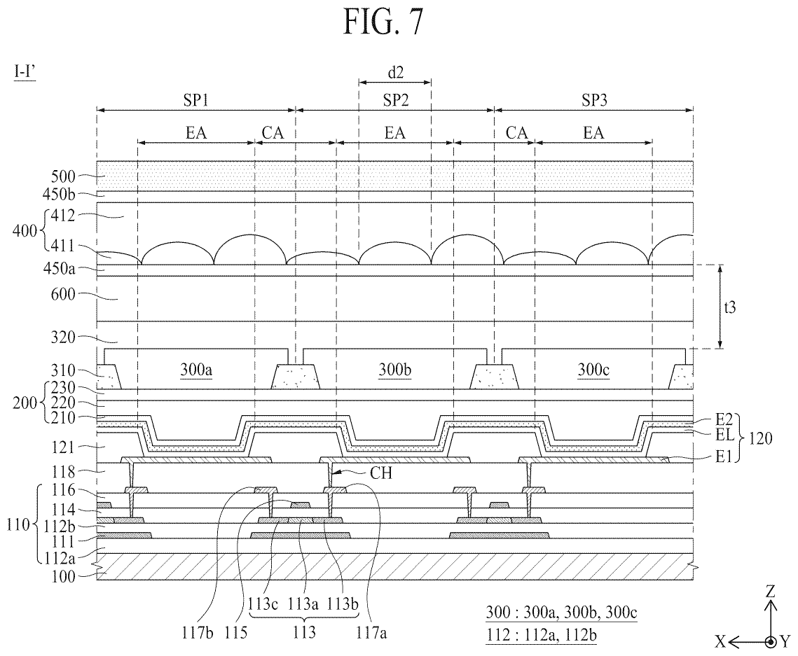

FIG. 7 is a cross-sectional view of an organic light emitting display apparatus according to another embodiment of the present disclosure. In this case, FIG. 7 corresponds to another example of a cross-section taken along line I-I′ illustrated in FIG. 1. Meanwhile, since the embodiment of FIG. 7 is the same as the embodiment of FIG. 6 except for the light transmitting member, the distance between the black matrix and the light guide part, and the plurality of lens patterns, the different configurations will be mainly described below.

Referring to FIG. 7, the organic light emitting display apparatus according to another embodiment of the present disclosure can further include a light transmitting member 600.

The light transmitting member 600 can be provided between the color filter 300 and the light guide part 400. Specifically, the light transmitting member 600 can contact the upper surface of the overcoating layer 320 and the lower surface of the light guide part 400 (e.g., lower surface of the lower adhesive member 450a).

Here, the light transmitting member 600 can perform the function of a privacy film by performing a viewing angle control function.

The light transmitting member 600 can transmit the light emitted from the plurality of subpixels SP and traveling vertically and block the light traveling in a predetermined inclined direction, so that the image implemented to travel the predetermined inclined direction may not be emitted to the outside of the second substrate 500. Accordingly, the light transmitting member 600 can prevent an image to be displayed in the organic light emitting display apparatus of the present disclosure from being viewed above a certain angle, which can provide privacy to the user.

Meanwhile, the light transmitting member 600 is not limited to a privacy film.

According to another embodiment of the present disclosure, by further providing the light transmission member 600, the black matrix 310 and the light guide member 400 can have a third thickness t3 being greater than the second thickness (see t2 in FIG. 6).

The third thickness t3 can exceed 600 μm and be equal to 1000 μm or less.

According to another embodiment of the present disclosure, when the third thickness t3 exceeds 600 μm and is equal to or less than 1000 μm, two or more patterns among the plurality of lens patterns 411 of the light guide part 400 can overlap any one of the light emitting areas EA. By forming in this way, light emitted from one of the light emitting areas EA can pass through two or more lens patterns among the plurality of lens patterns 411 that overlap the light emitting area EA. In other words, the plurality of lens patterns 411 can have a size d2 (e.g., width) that is less than ½ of the length (e.g., width) of the corresponding subpixel SP.

According to another embodiment of the present disclosure, since the deviation in the degree to which the light emitted from any one of the plurality of subpixels SP is refracted as it passes through the plurality of lens patterns 411 is reduced as a whole, Sparkle can be effectively and advantageously removed or minimized in the organic light emitting display apparatus according to another embodiment of the present disclosure.

The size d2 of each of the plurality of lens patterns 411 according to another embodiment of the present disclosure can exceed 0 and be 20 μm or less. The size d2 of each of the plurality of lens patterns 411 can preferably be 20 μm.

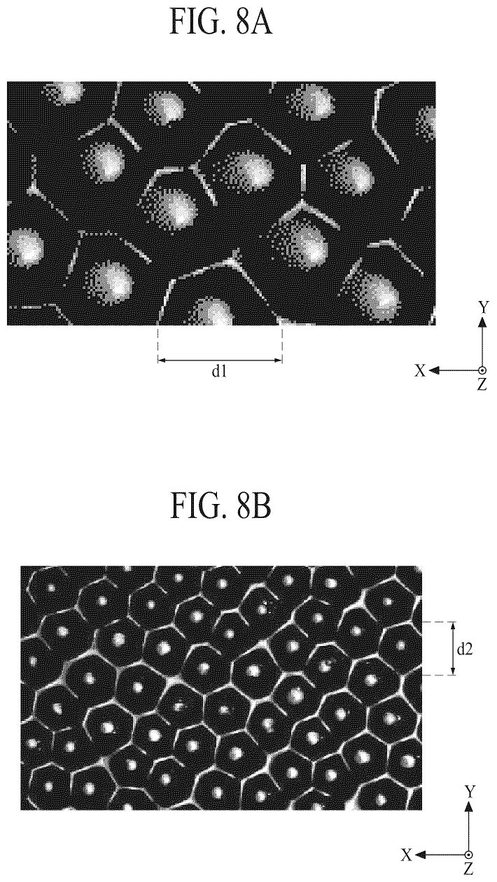

FIG. 8A illustrates the plurality of lens patterns 411 formed in a size of 35 μm according to an example of the present disclosure, and FIG. 8B illustrates the plurality of lens patterns 411 formed in a size of 20 μm according to an example of the present disclosure.

The plurality of lens patterns 411 according to the embodiment of FIG. 8A relate to a case in which the color filter 300 and the light guide part 400 are formed with the second thickness (see t2 of FIG. 6) like in the organic light emitting display apparatus of FIG. 6.

Since the sizes d1 of the plurality of lens patterns 411 of FIG. 8A are formed to be 35 μm, the deviation in the degree to which the light emitted from any one of the plurality of subpixels SP is refracted as it passes through the plurality of lens patterns 411 is reduced as a whole, so that Sparkle can be removed or minimized in the organic light emitting display apparatus of the present disclosure.

In another example, the plurality of lens patterns 411 according to the embodiment of FIG. 8B relate to a case in which the color filter 300 and the light guide part 400 are formed in the second thickness (see t2 of FIG. 6) or the third thickness (see t3 of FIG. 7), like in the organic light emitting display apparatus of FIGS. 6 and 7.

Since the size d2 of each of the plurality of lens patterns 411 of FIG. 8B is formed to have the size d2 of 20 μm, the deviation in the degree to which the light emitted from any one of the plurality of subpixels SP is refracted as it passes through the plurality of lens patterns 411 is reduced as a whole, so that Sparkle can be removed or minimized in the organic light emitting display apparatus of the present disclosure.

Accordingly, the present disclosure can have the following advantages.

According to an aspect of the present disclosure, since a plurality of lens patterns are irregularly formed atypically, a moire phenomenon caused by interference between the plurality of lens patterns and pixels can be addressed or minimized.

According to an aspect of the present disclosure, the light guide part includes a plurality of lens patterns and a lens connection part having a relatively low refractive index, and a filling layer having a relatively high refractive index. As a result, a limitation in which external light is reflected by electrodes and wires inside the display apparatus thereby forming Mura pattern, for example, Rainbow Mura or Ring Mura, is recognized can be minimized or eliminated.

According to an aspect of the present disclosure, by adjusting the size or height ratio of the plurality of lens patterns according to the distance between the black matrix and the light guide part, a sparkle phenomenon can be minimized or reduced by alleviating the degree of light refraction in the plurality of lens patterns, so that image quality can be improved and viewer visibility and user experience for an image can be improved.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. An organic light emitting display apparatus comprising:
a substrate including a first subpixel and a second subpixel;
a color filter layer including a first color filter disposed in the first subpixel on the substrate and a second color filter disposed in the second subpixel on the substrate;
a black matrix disposed between the first color filter and second color filter; and
a light guide part disposed on the first and second color filters of the color filter layer,
wherein the light guide part includes a plurality of lens patterns, and sizes of the plurality of lens patterns are larger than sizes of the first and second subpixels.

2. The organic light emitting display apparatus according to claim 1,
wherein the plurality of lens patterns include a first lens pattern and a second lens pattern, and the first lens pattern and the second lens pattern overlap each other.

3. The organic light emitting display apparatus according to claim 1,
wherein a height ratio H/D of each of the plurality of lens patterns ranges from 10% to 40%.

4. The organic light emitting display apparatus according to claim 1,
wherein a distance from a lower surface of the light guide part to an upper surface of the color filter layer is greater than 0 and equal to or less than 30 μm.

5. The organic light emitting display apparatus according to claim 1,
wherein the size of each of the plurality of lens patterns ranges from 10 μm to 100 μm.

6. The organic light emitting display apparatus according to claim 1,
wherein the light guide part further includes a lens connection part disposed between the plurality of lens patterns.

7. The organic light emitting display apparatus according to claim 1,
wherein the light guide part further includes a filling layer disposed on the plurality of lens patterns,
a first refractive index of the plurality of lens patterns is smaller than a second refractive index of the filling layer, and
a difference between the first refractive index and the second refractive index ranges from 0.10 to 0.40.

8. An organic light emitting display apparatus comprising:
a first subpixel and a second subpixel on a substrate;
a color filter layer including a first color filter disposed in the first subpixel on the substrate and a second color filter disposed in the second subpixel on the substrate;
a black matrix disposed between the first color filter and second color filter; and
a light guide part disposed on the first and second color filters of the color filter layer,
wherein the light guide part includes a plurality of lens patterns, and a size of at least one of the plurality of lens patterns is less than ½ of a length or size of at least one of the first and second subpixels.

9. The organic light emitting display apparatus according to claim 8,
wherein the plurality of lens patterns do not overlap each other.

10. The organic light emitting display apparatus according to claim 8,
wherein a distance from a lower surface of the light guide part to an upper surface of the color filter layer is greater than 30 μm and equal to or less than 600 μm.

11. The organic light emitting display apparatus according to claim 10,
wherein sizes of the plurality of lens patterns are greater than 0 and less than or equal to 35μ m.

12. The organic light emitting display apparatus according to claim 8,
wherein a distance from a lower surface of the light guide part to an upper surface of the color filter layer is greater than 600 μm and equal to or less than 1000 μm.

13. The organic light emitting display apparatus according to claim 12,
wherein sizes of the plurality of lens patterns are greater than 0 and less than or equal to 20μ m.

14. The organic light emitting display apparatus according to claim 8,
wherein the light guide part further includes a filling layer disposed on the plurality of lens patterns,
a first refractive index of the plurality of lens patterns is smaller than a second refractive index of the filling layer, and
a difference between the first refractive index and the second refractive index ranges from 0.10 to 0.40.

15. The organic light emitting display apparatus according to claim 8, further comprising:
a light transmitting member disposed between the plurality of lens patterns and the color filter layer and configured to provide a privacy function.

16. A light emitting display apparatus comprising:
a plurality of subpixels disposed on a substrate and including a light emitting element layer, each of the plurality of subpixels including a light emitting area and a circuit area;
an encapsulation layer disposed on the light emitting element layer;
a color filter layer including a plurality of color filters disposed to correspond with the light emitting areas of the plurality of subpixels; and
a light guide part disposed on the color filter layer, and including a plurality of lens patterns extending in both the light emitting area and the circuit area of each of the plurality of subpixels,
wherein the plurality of lens patterns in each of the plurality of subpixels have irregular sizes, and
for one of the plurality of subpixels, a size of one of the plurality of lens patterns in the light emitting area is smaller than a size of the light emitting area.

17. The light emitting display apparatus according to claim 16, further comprising:
an overcoating layer disposed between the color filter layer and the plurality of lens patterns,
wherein a distance between a lower surface of the plurality of lens patterns to an upper surface of the color filter layer exceeds 30 μm and is equal to or less than 600 μm.

18. The light emitting display apparatus according to claim 16, further comprising:
an overcoating layer disposed on the color filter layer; and
a light transmitting member disposed between the overcoating layer and the plurality of lens patterns,
wherein a distance between a lower surface of the plurality of lens patterns to an upper surface of the color filter layer exceeds 600 μm but is equal to or less than 1000 μm.

19. The light emitting display apparatus according to claim 16,
wherein the light guide part further includes a filling layer disposed on the plurality of lens patterns,
a first refractive index of one of the plurality of lens patterns is smaller than a second refractive index of the filling layer, and
a difference between the first refractive index and the second refractive index ranges from 0.10 to 0.40.

20. The light emitting display apparatus according to claim 16,
wherein in a top plan view, the plurality of lens patterns are composed of a plurality of lenses that are in contact with others and that have varying sizes.
